(19) United States
(12) Patent Application Publication
(10) Pub. No.: US 2008/0023717 A1
(43) Pub. Date: Jan. 31, 2008

(54) DISPLAY SUBSTRATE, METHOD OF MANUFACTURING THE SAME AND DISPLAY DEVICE HAVING THE SAME

(76) Inventors: Jin-Young Choi, Seoul (KR); Kee-Han Uh, Gyeonggi-do (KR); Jin Jeon, Gyeonggi-do (KR); Yong-Han Park, Gyeonggi-do (KR)

Correspondence Address: MACPHERSON KWOK CHEN & HEID LLP, 2033 GATEWAY PLACE, SUITE 400, SAN JOSE, CA, 95110, US

(21) Appl. No.: 11/828,252

(22) Filed: Jul. 25, 2007

(30) Foreign Application Priority Data
Jul. 27, 2006 (KR) 2006-70519

(51) Int. Cl. H01L 33/00; H01L 21/02

(52) U.S. Cl. 257/98; 438/29; 257/E33.001; 257/E21.532

(57) ABSTRACT

A display substrate capable of improving the signal transmission characteristics and image quality of a display device is presented. The display substrate includes a first conductive line on an insulating substrate. A storage capacitor line is on the insulating substrate. A storage capacitor line extends substantially parallel to the first conductive line. A second conductive line, which is also on the insulating substrate, extends in a direction different from the first conductive line and defines a pixel with the first conductive line. A light blocking pattern extends from the first conductive line, overlapping the second conductive line. A switching element is electrically connected to the first and second conductive lines and includes a drain electrode that is positioned on the storage capacitor line to form a storage capacitor. A pixel electrode is electrically connected to the drain electrode.

### CROSS-REFERENCE TO RELATED APPLICATIONS

The present application claims priority from Korean Patent Application No. 2006-70519 filed on Jul. 27, 2006, the disclosure of which is hereby incorporated herein by reference in its entirety.

### BACKGROUND OF THE INVENTION

1. Field of the Invention

The present invention relates to a display substrate, a method of manufacturing the display substrate and a display device having the display substrate. More particularly, the present invention relates to a display substrate capable of improving signal transmission characteristics, a method of manufacturing the display substrate and a display device having the display substrate.

2. Description of the Related Art

A flat panel display device has advantageous characteristics such as thinness, light weight, small size, etc. Thus, the flat panel display device has been widely used in various fields.

A flat panel display device includes a pixel and a light blocking pattern. An image is displayed on the pixel. The light blocking pattern blocks light that is not incident on a display region.

In order to form the light blocking pattern, an opaque material layer is deposited on a cover substrate of the display device and partially removed through a photolithography process.

The photolithography process includes exposure to light, a development process, etc. Thus, the manufacturing process of the display device is complex and expensive. In addition, the width of the light blocking pattern is usually increased to decrease the light leakage caused by any misalignment. This increased with of the light blocking pattern undesirably reduces the opening ratio of the pixel.

In addition, the load of a signal applied to a conductive pattern is increased by the light blocking pattern so that the speed of the signal transmission is slowed down by RC delay. Furthermore, a parasitic capacitance formed between a conductive line and the conductive pattern adjacent to the light blocking pattern is increased. These factors contribute to deterioration of the image display quality of the display device.

### SUMMARY OF THE INVENTION

The present invention provides a display substrate capable of improving signal transmission characteristics.

The present invention also provides a method of manufacturing the above-mentioned display substrate.

The present invention also provides a display device having the display substrate.

In accordance with one aspect, the present invention includes a first conductive line, a storage capacitor line, a second conductive line, a light blocking pattern, a switching element and a pixel electrode. The first conductive line is on an insulating substrate. The storage capacitor line is on the insulating substrate and extends substantially parallel to the first conductive line. The second conductive line is on the insulating substrate. The second conductive line extends in a direction different from the first conductive line and defines a pixel with the first conductive line. The light blocking pattern extends from the first conductive line and overlaps the second conductive line. The switching element is electrically connected to the first and second conductive lines. The switching element includes a drain electrode that is positioned over the storage capacitor line to form a storage capacitor. The pixel electrode, which is in the pixel, is electrically connected to the drain electrode.

In accordance with another aspect, the present invention includes a first conductive line, a storage capacitor line, a second conductive line, a third conductive line, a light blocking pattern, a switching element and a pixel electrode. The first conductive line is on an insulating substrate. The storage capacitor line is on the insulating substrate. The storage capacitor line extends substantially parallel to the first conductive line. The second conductive line is on the insulating substrate and extends in a direction different from the first conductive line. The first and second conductive lines define a pixel. The third conductive line is spaced apart from the storage capacitor line on the insulating substrate and extends substantially parallel to the first conductive line. The light blocking pattern extends from the third conductive line and overlaps the second conductive line. The switching element is electrically connected to the first and second conductive lines. The switching element includes a drain electrode positioned on the storage capacitor line to form a storage capacitor. The pixel electrode, which is in the pixel, is electrically connected to the drain electrode.

In yet another aspect, the present invention is a method of manufacturing a display substrate. In the method, a conductive line is formed on an insulating substrate. The conductive line is patterned to form a gate line, a gate electrode electrically connected to the gate line, a storage capacitor line extending substantially parallel to the gate line. and a light blocking pattern extending from the gate line. A data line overlaps the light blocking pattern, a source electrode electrically connected to the data line, and a drain electrode spaced apart from the source electrode are formed. The drain electrode is positioned on the storage capacitor line. A pixel electrode is formed in a pixel defined by the gate and data lines, the pixel electrode being electrically connected to the drain electrode.

In accordance with yet another aspect, the present invention is a method of manufacturing a display substrate. In the method, a conductive line is formed on an insulating substrate. The conductive line is patterned to form a gate line, a gate electrode electrically connected to the gate line, a storage capacitor line extending substantially parallel to the gate line, a compensation voltage supplying line extending substantially parallel to the gate line to be spaced apart from the storage capacitor line and a light blocking pattern extending from the compensation voltage supplying line. A data line overlapped with the light blocking pattern, a source electrically connected to the data line and a drain electrode spaced apart from the source electrode are formed. The drain electrode is positioned on the storage capacitor line. A pixel electrode is formed in a pixel defined by the gate and data lines. The pixel electrode is electrically connected to the drain electrode.

In yet another aspect, the invention is a display device in accordance with still another aspect of the present invention includes a display substrate, a cover substrate and a liquid crystal layer. The display substrate includes a first conductive line, a storage capacitor line, a second conductive line, a third conductive line, a light blocking pattern, a switching element and a pixel electrode. The first conductive line is on an insulating substrate. The storage capacitor line is on the insulating substrate. The storage capacitor line extends substantially parallel to the first conductive line. The second conductive line is on the insulating substrate. The second conductive line extends in a different direction than the first conductive line to define a pixel. The third conductive line is spaced apart from the storage capacitor line on the insulating substrate. The third conductive line extends substantially parallel to the first conductive line. The light blocking pattern extends from the third conductive line and overlaps the second conductive line. The switching element is electrically connected to the first and second conductive lines. The switching element includes a drain electrode positioned on the storage capacitor line to form a storage capacitor. The pixel electrode is electrically connected to the drain electrode. The pixel electrode is in the pixel. The cover substrate includes a common electrode on the pixel electrode. The liquid crystal layer is interposed between the display substrate and the cover substrate.

The display substrate may be used for a liquid crystal display (LCD) device, an organic light emitting display (OLED) device, a plasma panel display (PDP) device, etc.

According to the present invention, a parasitic capacitance is decreased, and a load of the gate line and the storage capacitor line is decreased. Thus, an image display quality of the display device is improved. In addition, a manufacturing process of the display substrate is simplified, and a manufacturing cost of the display substrate is decreased.

### BRIEF DESCRIPTION OF THE DRAWINGS

The above and other advantages of the present invention will become more apparent through descriptions of embodiments with reference to the accompanying drawings, in which:

FIG. 1 is a plan view illustrating a display substrate in accordance with one embodiment of the present invention;

FIG. 2 is a cross-sectional view taken along the line I-I′ shown in FIG. 1;

FIGS. 3 to 6 are cross-sectional views illustrating a method of manufacturing the display substrate shown in FIG. 1;

FIG. 7 is a plan view illustrating a display device in accordance with another embodiment of the present invention;

FIG. 8 is a plan view illustrating a display substrate in accordance with yet another embodiment of the present invention;

FIG. 9 is a cross-sectional view taken along the line II-II′ shown in FIG. 8;

FIG. 10 is a plan view illustrating a display substrate in accordance with yet another embodiment of the present invention;

FIG. 11 is a plan view illustrating a display substrate in accordance with yet another embodiment of the present invention;

FIG. 12 is a plan view illustrating a display substrate in accordance with yet another embodiment of the present invention; and

FIG. 13 is a plan view illustrating a display substrate in accordance with yet another embodiment of the present invention.

### DESCRIPTION OF THE EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-sectional illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be described in detail with reference to the accompanying drawings.

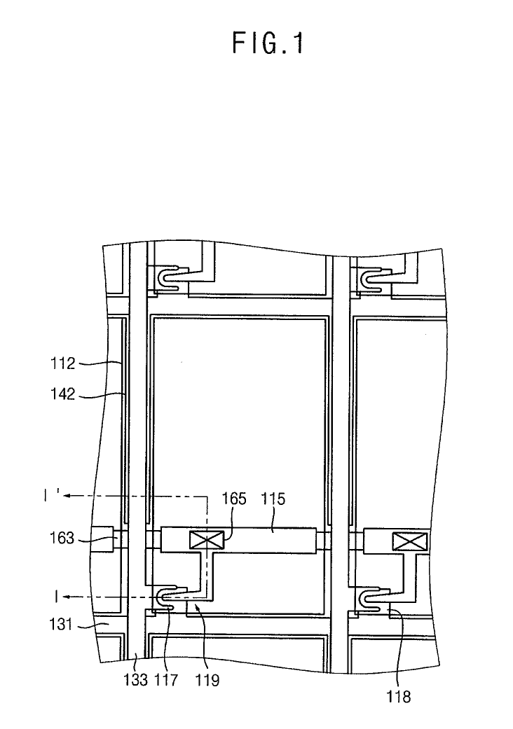

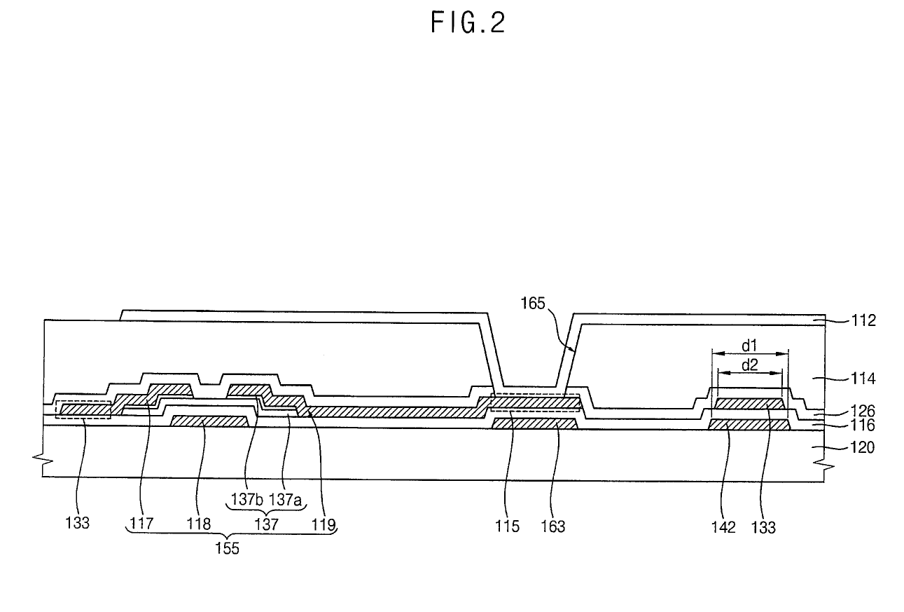

FIG. 1 is a plan view illustrating a display substrate in accordance with one embodiment of the present invention. FIG. 2 is a cross-sectional view taken along the line I-I′ shown in FIG. 1.

Referring to FIGS. 1 and 2, the display substrate includes an insulating substrate 120, a gate line 131, a light blocking pattern 142, a storage capacitor line 163, a gate insulating layer 116, a semiconductor pattern 137, a source electrode 117, a drain electrode 119, a data line 133, a passivation layer 126, an organic insulating layer 114 and a pixel electrode 112.

The insulating substrate 120 includes a transparent material that transmits light. Examples of the transparent material that can be used for the insulating substrate 120 include glass, quartz, synthetic resin, etc. These can be used alone or in combination. In FIGS. 1 and 2, the insulating substrate 120 may be optically isotropic or anisotropic, depending on the embodiment.

The gate line 131 is on the insulating substrate 120. The gate lines 131 may extend substantially parallel to each other.

The storage capacitor line 163 is on the insulating substrate 120 and extends substantially parallel to the gate line 131. The storage capacitor line 163 is between the gate lines 131. A common voltage may be applied to the storage capacitor line 163.

The gate insulating layer 116 is on the insulating substrate 120 to cover the gate line 131, the storage capacitor line 163, a gate electrode 118 of the thin film transistor 155 and a light blocking pattern 142. The gate insulating layer 116 includes an insulating material that transmits light. Examples of the insulating material that can be used for the gate insulating layer 116 include silicon nitride, silicon oxide, etc.

The data line 133 is on the gate insulating layer 116 and extends in a direction different from the gate line 131, such that the data line 133 and the gate line 131 together define a plurality of pixels.

The light blocking pattern 142 extends from the gate line 131 and overlaps the data line 133. For example, an end portion of the light blocking pattern 142 is adjacent to the storage capacitor line 163 to face a side of the storage capacitor line 163. The light blocking pattern 142 is formed from substantially the same layer as the gate line 131 and the storage capacitor line 163. When a light blocking pattern is electrically insulated from a gate line to be floated, a parasitic capacitance between the data line and a pixel electrode increases so that a speed of the signal transmission is slowed down by RC delay. However, in FIGS. 1 and 2, the light blocking pattern 142 is electrically connected to the gate line 131 so that the parasitic capacitance formed between the data line 131 and the pixel electrode 112 is decreased.

In FIGS. 1 and 2, the width d1 of the light blocking pattern 142 is greater than the width d2 of the data line 133.

The light blocking pattern 142 includes a conductive material. Examples of the conductive material that can be used for the light blocking pattern 142 include molybdenum, aluminum, copper, chromium, niobium, tungsten, etc. These can be used alone, in an alloy thereof, or in combination. Alternatively, the light blocking pattern 142 may have a multi layered structure including a plurality of metal layers.

The thin film transistor 155 is on the insulating substrate 120 and includes the gate electrode 118, a semiconductor pattern 137, a source electrode 117 and a drain electrode 119. When a voltage difference is applied between the gate electrode 118 and the source electrode 117, a channel is formed in the semiconductor pattern 137 that electrically connects the source electrode 117 and the drain electrode 119 so that a data signal is applied to the pixel electrode 112.

The gate electrode 118 is on the insulating substrate 120, and is electrically connected to the gate line 131.

The semiconductor pattern 137 is on the gate insulating layer 116 corresponding to the gate electrode 118, and includes an amorphous silicon pattern 137a and an n+ amorphous silicon pattern 137b on the amorphous silicon pattern 137a.

The source electrode 117 is on the semiconductor pattern 137 to be electrically connected to the data line 133.

The drain electrode 119 is spaced apart from the source electrode 117 on the semiconductor pattern 137. The drain electrode 119 includes a storage electrode portion 115, and is electrically connected to the pixel electrode 112 through a contact hole 165. The contact hole 165 is formed through the passivation layer 126 and the organic insulating layer 114.

The storage electrode portion 115 of the drain electrode 119 overlaps the storage capacitor line 163, and the gate insulating layer 116 is interposed between the storage electrode portion 115 and the storage capacitor line 163. Thus, the storage electrode portion 115, the storage capacitor line 163 and the gate insulating layer 116 form a storage capacitor. When a storage capacitor includes a storage capacitor line, a pixel electrode and a dielectric assembly that includes a gate insulating layer, a passivation layer and an organic layer interposed between the storage capacitor line and the pixel electrode, the distance between the storage capacitor line and the pixel electrode is increased so that the capacitance of the storage capacitor is decreased. However, in FIGS. 1 and 2, the distance between the storage capacitor line 163 and the storage electrode portion 115 is decreased so that the capacitance of the storage capacitor is increased.

In FIGS. 1 and 2, the storage electrode portion 115 extends substantially parallel to the storage capacitor line 163.

The passivation layer 126 is on the gate insulating layer 116 to cover the semiconductor pattern 137, the data line 133, the source electrode 117 and the drain electrode 119. The passivation layer 126 includes an insulating material that transmits light. Examples of the insulating material that can be used for the passivation layer 126 include silicon nitride, silicon oxide, etc.

The organic insulating layer 114 is on the passivation layer 126 to planarize a surface of the display substrate. The passivation layer 126 and the organic insulating layer 114 include the contact hole 165 through which the storage electrode portion 115 of the drain electrode 119 is partially exposed.

The pixel electrode 112 is on the organic insulating layer 114, and is electrically connected to the drain electrode 119 through the contact hole 165. The pixel electrode 112 includes a transparent conductive material. Examples of the transparent conductive material that can be used for the pixel electrode 112 include indium tin oxide (ITO), indium zinc oxide (IZO), indium tin zinc oxide (ITZO), amorphous indium tin oxide (a-ITO), etc.

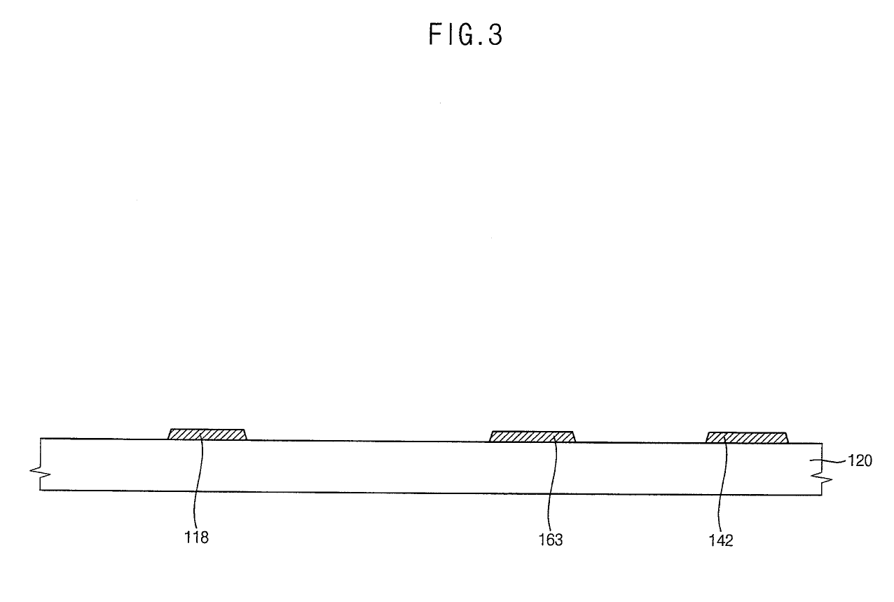

FIGS. 3 to 6 are cross-sectional views illustrating a method of manufacturing the display substrate shown in FIG. 1.

Referring to FIGS. 1 and 3, a gate metal layer (not shown) is deposited on the insulating substrate 120. The gate metal layer is partially etched through a photolithography process to form the gate line 131, the gate electrode 118, the light blocking pattern 142 and the storage capacitor line 163.

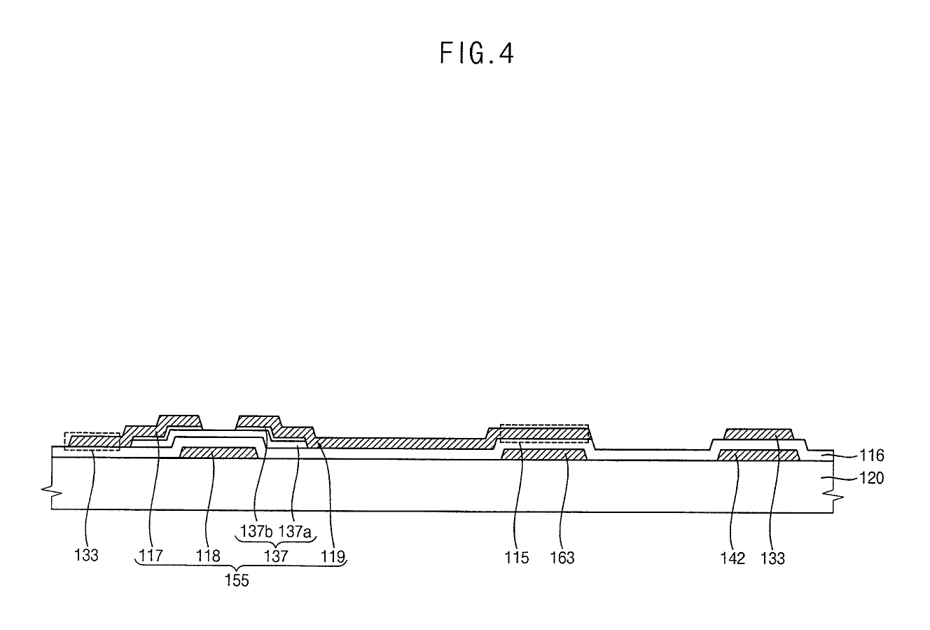

Referring to FIG. 4, the gate insulating layer 116 is deposited on the insulating substrate 120 to cover the gate line 131, the gate electrode 118, the light blocking pattern 142 and the storage capacitor line 163.

An amorphous silicon layer (not shown) and an n+ amorphous silicon layer (not shown) are formed on the gate insulating layer 116. For example, a primary amorphous silicon layer (not shown) is deposited on the gate insulating layer 116, and n+ impurities are implanted onto an upper portion of the primary amorphous silicon layer to form the amorphous silicon layer and the n+ amorphous silicon layer. Alternatively, the amorphous silicon layer and the n+ amorphous silicon layer may be directly deposited on the gate insulating layer 116.

The amorphous silicon layer and the n+ amorphous silicon layer are patterned through a photolithography process to form the amorphous silicon pattern 137a and the n+ amorphous silicon pattern 137b.

A data metal layer (not shown) is deposited on the gate insulating layer 116. The data metal layer is partially removed through a photolithography process to form the data line 133, the source electrode 117 and the drain electrode 119. For example, a portion of the n+ amorphous silicon pattern interposed between the source electrode 117 and the drain electrode 119 may be etched using the source electrode 117 and the drain electrode 119 as an etching mask so that the amorphous silicon pattern 137a is partially exposed.

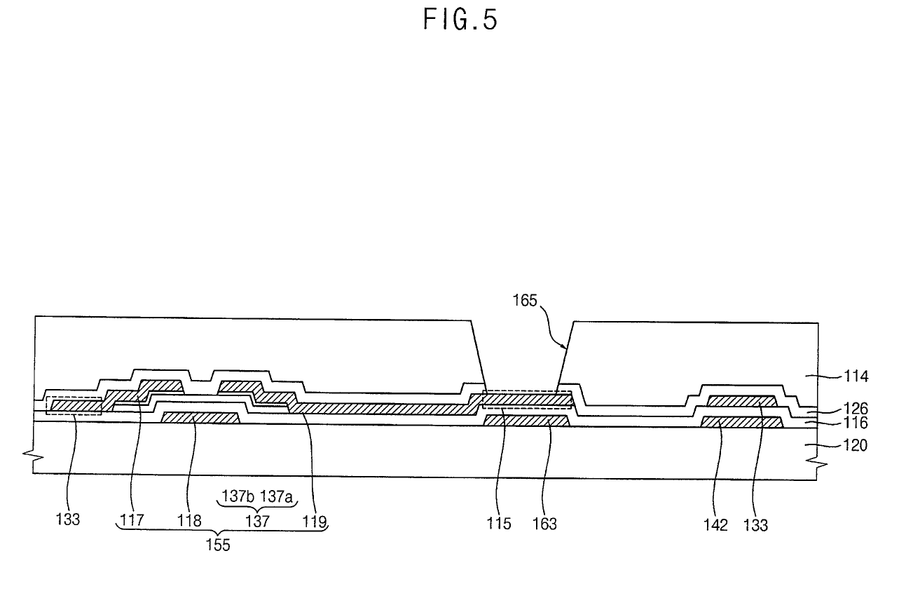

Referring to FIG. 5, the passivation layer 126 is deposited on the gate insulating layer 116 to cover the data line 133, the source electrode 117 and the drain electrode 119.

The organic insulating layer 114 is formed on the passivation layer 126.

The organic insulating layer 114 and the passivation layer 126 are partially removed to form the contact hole 165 that extends to the storage electrode portion 115 of the drain electrode 119.

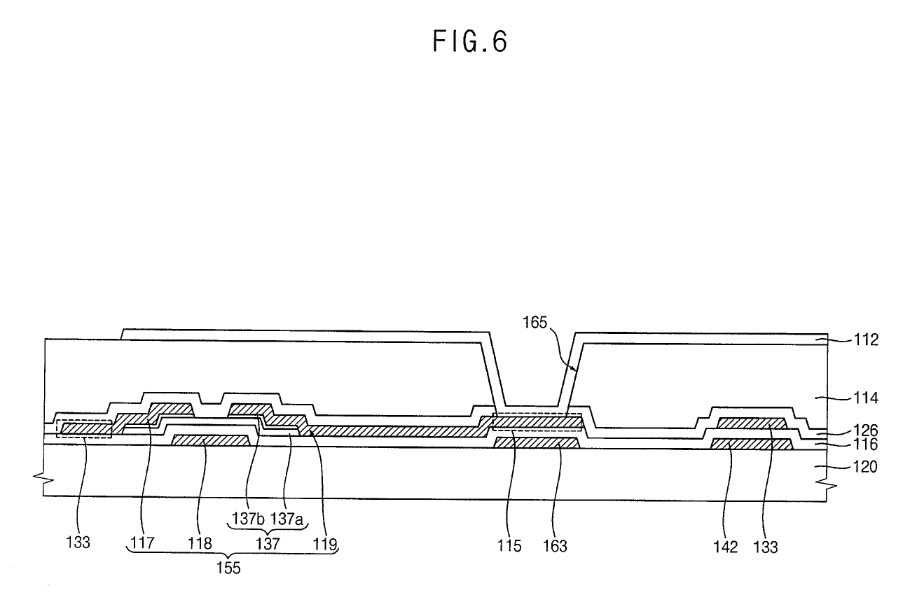

Referring to FIG. 6, a transparent conductive layer is formed on an inner surface of the contact hole 165 and the organic insulating layer 114. The transparent conductive layer is patterned to form the pixel electrode 112.

According to the display substrate and the method of manufacturing the display substrate of FIGS. 1 to 6, the light blocking pattern 142 is electrically connected to the gate line 131 to decrease the parasitic capacitance between the data line 131 and the pixel electrode 112.

In addition, the light blocking pattern 142 is formed from substantially the same layer as the gate line 131 so that the manufacturing process of the display substrate is simplified and the manufacturing cost of the display substrate is decreased.

Furthermore, the light blocking pattern 142 that is electrically connected to the gate line 131 may function as a shielding capacitor for decreasing a fringe field that may form between adjacent pixel electrodes 112, thereby decreasing light leakage between the adjacent pixel electrodes 112.

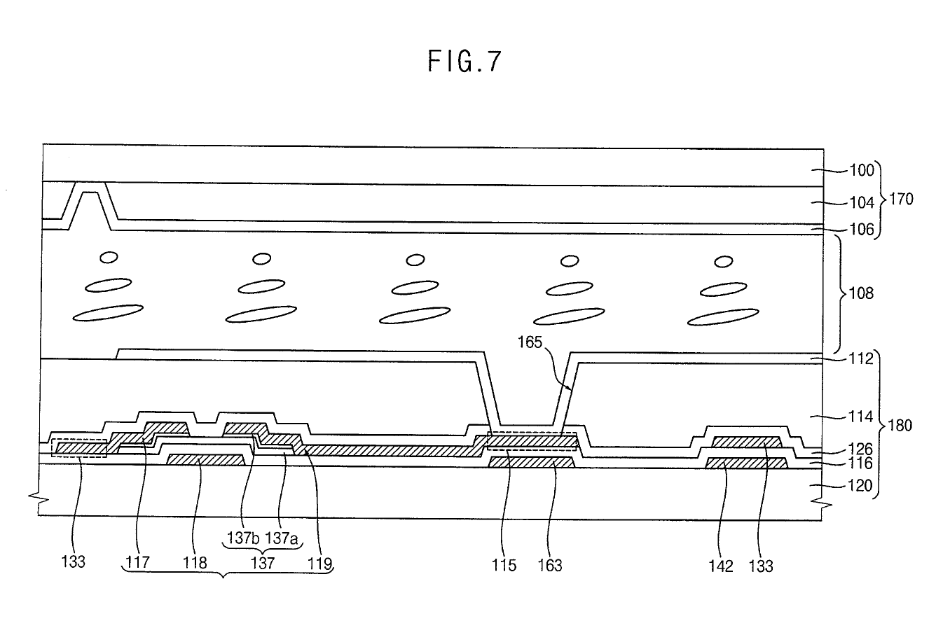

FIG. 7 is a plan view illustrating a display device in accordance with another embodiment of the present invention.

Referring to FIG. 7, the display device includes a display substrate 180, a cover substrate 170, and a liquid crystal layer 108. The display substrate 180 of FIG. 7 is substantially the same as that of FIGS. 1 and 2. Thus, the same reference numerals will be used to refer to the same or like parts as those described in FIGS. 1 and 2 and any redundant explanation concerning the already-described elements will be omitted.

The cover substrate 170 includes an insulating substrate 100, a color filter 104 and a common electrode 106.

The insulating substrate 100 includes a transparent insulating material. In FIG. 7, the insulating substrate 100 may include substantially the same material as an insulating substrate 120 of the display substrate 180.

A black matrix (not shown) may be formed on the insulating substrate 100 to block light that passed through a region between adjacent pixel electrodes 112. In order to compensate for any misalignment between the cover substrate 170 and the display substrate 180, the width of the black matrix may be greater than the distance between adjacent pixel electrodes 112. Generally, when the width of the black matrix is increased, the opening ratio of the display device decreases. However, in FIG. 7, the display substrate 180 includes a light blocking pattern 142 so that the black matrix does not need to be made wider, avoiding any decrease in the opening ratio. If desired, the black matrix may be omitted entirely to increase the opening ratio.

The color filter 104 is on the insulating substrate 100 to transmit light having a predetermined wavelength. The color filter 104 corresponds to the pixel electrode 112 of the display substrate 180.

The common electrode 106 includes a transparent conductive material. Examples of transparent conductive material that can be used for the common electrode 106 include indium zinc oxide (IZO), indium tin oxide (ITO), indium tin zinc oxide (ITZO), amorphous indium tin oxide (a-ITO), etc.

The display device may further include a spacer (not shown) interposed between the display substrate 180 and the cover substrate 170. The spacer maintains a distance between the display substrate 180 and the cover substrate 170.

The liquid crystal layer 108 is interposed between the display substrate 180 and the cover substrate 170. Liquid crystals of the liquid crystal layer 108 adjust their arrangement in response to an electric field applied between the common electrode 105 and the pixel electrode 112, and light transmittance of the liquid crystal layer 108 changes according to the crystal arrangement. This way, an image having a desired gray-scale can be displayed.

The display device may further include a sealant (not shown) interposed between the display substrate 180 and the cover substrate 170 to seal the liquid crystal layer 108.

According to the display device of FIG. 7, the display device 180 includes the light blocking pattern 142 so that a portion or the entire black matrix may be omitted. Thus, the opening ratio of the display device is increased.

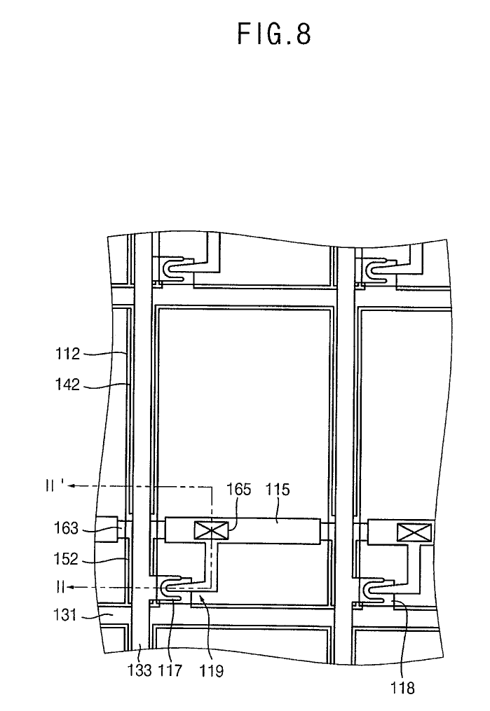

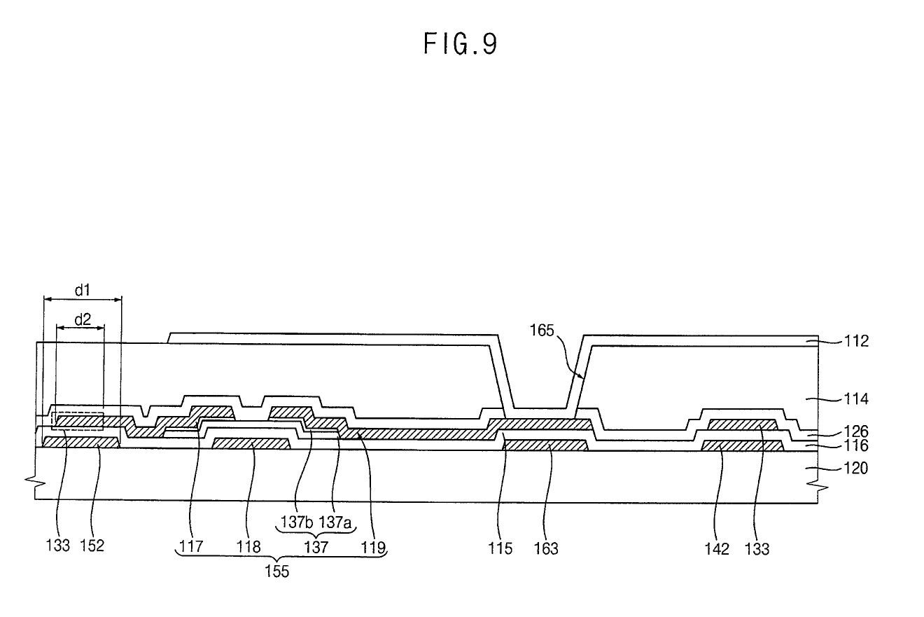

FIG. 8 is a plan view illustrating a display substrate in accordance with yet another embodiment of the present invention. FIG. 9 is a cross-sectional view taken along the line II-II′ shown in FIG. 8. The display substrate of FIGS. 8 and 9 is substantially the same as that of FIGS. 1 and 2 except for the presence of an auxiliary light blocking pattern. Thus, the same reference numerals will be used to refer to the same or like parts as those described in FIGS. 1 and 2 and any redundant explanation concerning already-described elements will be omitted.

Referring to FIGS. 8 and 9, the auxiliary light blocking pattern 152 extends from a storage capacitor line 163 to overlap the data line 133. The auxiliary light blocking pattern 152 is formed from substantially the same layer as the gate line 131, the light blocking pattern 142 and the storage capacitor line 163.

In FIGS. 8 and 9, the auxiliary light blocking pattern 152 has substantially the same width d1 as the light blocking pattern 142. The width d1 of the auxiliary light blocking pattern 152 is greater than the width d2 of the data line 133.

The light blocking pattern 152 includes a conductive material that blocks light. For example, the auxiliary light blocking pattern 152 includes substantially the same material as the light blocking pattern 142.

In FIGS. 8 and 9, the light blocking pattern 142 extends from the gate line 131 in a downward vertical direction in FIG. 8. The auxiliary light blocking pattern 152 extends from the storage capacitor line 163 also extends in the downward vertical direction in FIG. 8. Alternatively, the light blocking pattern may extend from the gate line in the upward vertical direction in FIG. 8, and the auxiliary light blocking pattern may extend from the storage capacitor line in the upward vertical direction in FIG. 8.

According to the display substrate of FIGS. 8 and 9, the display substrate 180 includes the light blocking pattern 142 and the auxiliary light blocking pattern 152 so that light leakage of a display device having the display substrate 180 is decreased, and the image display quality of the display device is improved.

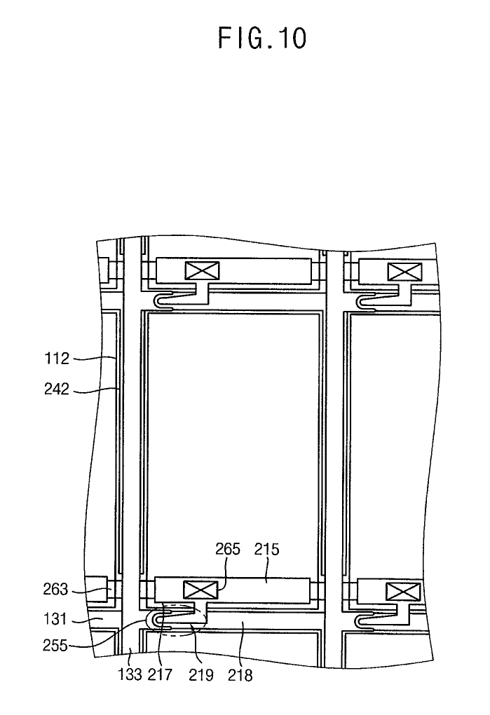

FIG. 10 is a plan view illustrating a display substrate in accordance with another embodiment of the present invention. The display substrate of FIG. 10 is substantially the same as that of FIGS. 1 and 2 except for a storage capacitor line and a thin film transistor. Thus, the same reference numerals will be used to refer to the same or like parts as those described in FIGS. 1 and 2 and any redundant explanation concerning already-described elements will be omitted.

Referring to FIG. 10, a thin film transistor 255 is interposed between adjacent pixel electrodes 112. The thin film transistor 255 includes a gate electrode 218, a semiconductor pattern 137 (shown in FIG. 2), a source electrode 217 and a drain electrode 219.

The gate electrode 218 is on the gate line 131. In an exemplary embodiment, the gate electrode 218 may be wider than the gate line 131.

The storage capacitor line 263 is positioned close to the gate line 131 so that the distance between the storage capacitor line 263 and the gate line 131 is decreased.

The drain electrode 219 includes a storage electrode portion 215. The drain electrode 219 overlaps the storage capacitor line 263.

The light blocking pattern 242 extends from the gate line 131 to overlap the data line 133. In FIG. 10, the distance between the storage capacitor line 263 and the gate line 131 is decreased so that the length of the light blocking pattern 242 is increased.

According to the display substrate of FIG. 10, the distance between the storage capacitor line 263 and the gate line 131 is decreased so that an auxiliary light blocking pattern 152 (shown in FIG. 8) may be omitted in a region between the storage capacitor line 263 and the gate line 131. This way, light leakage between the storage capacitor line 263 and the gate line 131 is decreased even if the auxiliary light blocking pattern 152 is omitted.

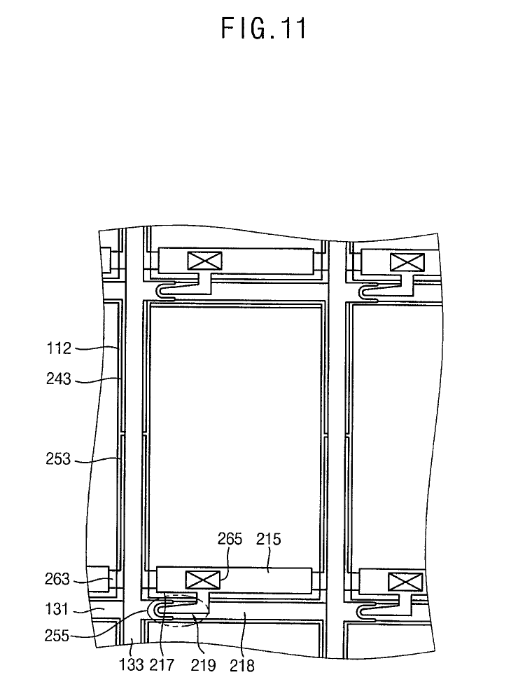

FIG. 11 is a plan view illustrating a display substrate in accordance with yet another embodiment of the present invention. The display substrate of FIG. 11 is the same as that of FIG. 10 except for the light blocking pattern and the auxiliary light blocking pattern. Thus, the same reference numerals will be used to refer to the same or like parts as those described in FIG. 10 and any redundant explanation concerning already-described elements will be omitted.

Referring to FIG. 11, the light blocking pattern 243 extends from the gate line 131 overlapping and partly tracking the data line 133. The light blocking pattern 243 extends from the gate line 131 in a downward vertical direction in FIG. 11. The length of the light blocking pattern 243 may be about half of the distance between the gate line 131 and a storage capacitor line 263.

The light blocking pattern 243 is formed from the same layer as the gate line 131 and the storage capacitor line 263. The light blocking pattern 243 may be wider than the data line 133.

The auxiliary light blocking pattern 253 extends from the storage capacitor line 263 overlapping a partly tracking the data line 133. The auxiliary light blocking pattern 253 extends from the storage capacitor line 263 in an upward vertical direction in FIG. 11. The length of the auxiliary light blocking pattern 253 may be about half of the distance between the gate line 131 and the storage capacitor line 263.

The auxiliary light blocking pattern 253 may be formed from the same layer as the gate line 131, the storage capacitor line 263, and the light blocking pattern 243. The width of the auxiliary light blocking pattern 253 may be substantially the same as the width of the light blocking pattern 243, and may be greater than the width of the data line 133.

According to the display substrate of FIG. 11, the display substrate includes the light blocking pattern 243 and the auxiliary light blocking pattern 253 so that the length of the light blocking pattern 243 may be decreased. Thus, the load on the gate line 131 is decreased, improving the image display quality of a display device including the display substrate.

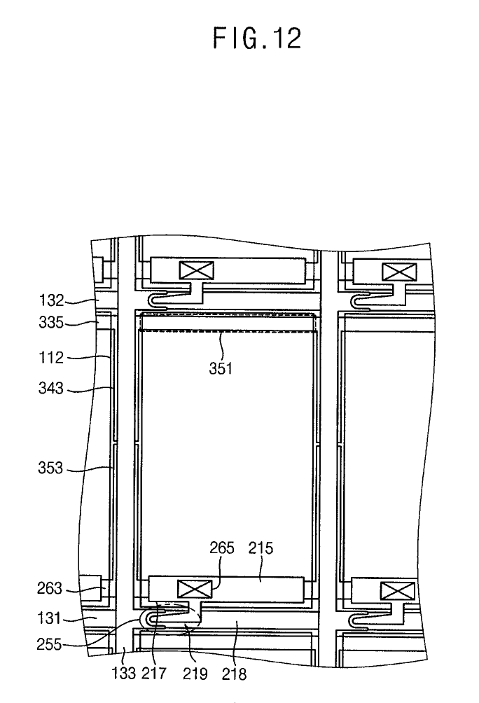

FIG. 12 is a plan view illustrating a display substrate in accordance with yet another embodiment of the present invention. The display substrate of FIG. 12 is substantially the same as that of FIG. 11 except for a compensation voltage supplying line. Thus, the same reference numerals will be used to refer to the same or like parts as those described in FIG. 11 and any redundant explanation concerning already-described elements will be omitted.

Referring to FIG. 12, the compensation voltage supplying line 335 is on an insulating substrate 120 (shown in FIG. 2). The compensation voltage supplying line 335 extends substantially parallel to the gate line 131. For example, the compensation voltage supplying line 335 is adjacent to the gate line 132 of an adjacent pixel.

In FIG. 12, a direct current voltage is applied to the compensation voltage supplying line 335. For example, a level of the direct current voltage applied to the compensation voltage supplying line 335 may be substantially the same as the average level of a data signal applied to the data line 133. In addition, a common voltage may be applied to the compensation voltage supplying line 335.

A light blocking pattern 343 extends from the compensation voltage supplying line 335 overlapping and partly tracking the data line 133. The light blocking pattern 343 extends from the compensation voltage supplying line 335 in a downward vertical direction in reference to FIG. 12. The length of the light blocking pattern 334 may be about half of the distance between the compensation voltage supplying line 335 and a storage capacitor line 263.

An auxiliary light blocking pattern 353 extends from the storage capacitor line 263 overlapping and partly tracking the data line 133. The auxiliary light blocking pattern 353 extends from the storage capacitor line 263 toward the compensation voltage supplying line 335. The length of the auxiliary light blocking pattern 353 may be about half of the distance between the compensation voltage supplying line 335 and the storage capacitor line 263.

According to the display substrate of FIG. 12, the display substrate includes the compensation voltage supplying line 335 to reduce the load on the gate line 132.

In addition, the compensation voltage supplying line 335 partially overlaps the pixel electrode 112 to form an auxiliary storage capacitor 351 that maintains a voltage difference between the pixel electrode 112 and a common electrode 106 (shown in FIG. 7). An auxiliary storage electrode (not shown) may be interposed between the gate insulating layer 116 (shown in FIG. 2) and the passivation layer 126 (shown in FIG. 2), and the pixel electrode 112 may be electrically connected to the auxiliary storage electrode through a contact hole that is formed through the gate insulating layer and the passivation layer.

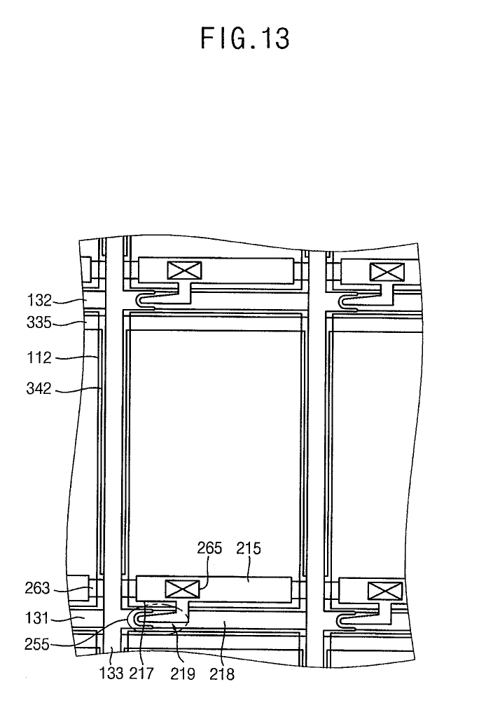

FIG. 13 is a plan view illustrating a display substrate in accordance with yet another embodiment of the present invention. The display substrate of FIG. 13 is substantially the same as that of FIG. 10 except for the compensation voltage supplying line. Thus, the same reference numerals will be used to refer to the same or like parts as those described in FIG. 10 and any redundant explanation concerning already-described elements will be omitted.

Referring to FIG. 13, the compensation voltage supplying line 335 is on an insulating substrate 120 (shown in FIG. 2). The compensation voltage supplying line 335 extends in a direction substantially parallel to the gate line 131. For example, the compensation voltage supplying line 335 is adjacent to the gate line 132 of a neighboring pixel.

A light blocking pattern 342 extends toward the compensation voltage supplying line 335 overlapping and partly tracking the data line 133. The light blocking pattern 342 extends from the compensation voltage supplying line 335 in a downward vertical direction in reference to FIG. 13. The length of the light blocking pattern 342 may be substantially the same as the distance between the compensation voltage supplying line 335 and the storage electrode portion 215.

According to the display substrate of FIG. 13, the length of the light blocking pattern 342 is increased so that an auxiliary light blocking pattern 354 (shown in FIG. 12) that extends from the storage capacitor line 263 may be omitted. This way, the load on the storage capacitor line 263 is decreased so that the capacitance of the storage capacitor may be increased. In addition, the compensation voltage supplying line 335 may partially overlap the pixel electrode 112 to form an auxiliary storage capacitor.

According to the present invention, the light blocking pattern is electrically connected to the gate line so that any parasitic capacitance between the data line and the pixel electrode is decreased. In addition, the light blocking pattern is formed from substantially the same layer as the gate line so that a manufacturing process of the display substrate is simplified, and the manufacturing cost of the display substrate is decreased.

In addition, the display substrate includes the compensation voltage supplying line so that the loads on the gate line and the storage capacitor line are decreased.

Furthermore, the compensation voltage supplying line partially overlaps the pixel electrode to form the auxiliary storage capacitor that maintains the voltage difference between the pixel electrode and the common electrode.

Also, the light blocking pattern electrically connected to the gate line may function as the shielding capacitor that decreases the fringe field formed between the adjacent pixel electrodes, thereby decreasing light leakage.

For the above reasons, the image display quality of the display device is improved.

This invention has been described with reference to the example embodiments. It is evident, however, that many alternative modifications and variations will be apparent to those having skill in the art in light of the foregoing description. Accordingly, the present invention embraces all such alternative modifications and variations as fall within the spirit and scope of the appended claims.

What is claimed is:

1. A display substrate comprising:
a first conductive line on an insulating substrate;
a storage capacitor line on the insulating substrate, the storage capacitor line extending in a direction substantially parallel to the first conductive line;
a second conductive line on the insulating substrate, the second conductive line extending in a direction different from the first conductive line, the first and the second conductive lines defining a pixel;
a light blocking pattern extending from the first conductive line and overlapping the second conductive line;
a switching element electrically connected to the first and second conductive lines, the switching element including a drain electrode that is formed on the storage capacitor line to form a storage capacitor; and
a pixel electrode in the pixel electrically connected to the drain electrode.

2. The display substrate of claim 1, further comprising an insulating layer on the insulating substrate to cover the first conductive line, the storage capacitor line and the light blocking pattern.

3. The display substrate of claim 2, wherein the first conductive line, the storage capacitor line and the light blocking pattern are formed from the same layer.

4. The display substrate of claim 2, further comprising an auxiliary light blocking pattern disposed between the insulating substrate and the insulating layer, the auxiliary light blocking pattern extending from the storage capacitor line and overlapping with the second conductive line.

5. The display substrate of claim 4, wherein each of the light blocking pattern and the auxiliary light blocking pattern is wider than a width of the second conductive line.

6. The display substrate of claim 4, wherein the light blocking pattern and the auxiliary light blocking pattern extend toward opposite ends of the display substrate.

7. The display substrate of claim 4, wherein the light blocking pattern and the auxiliary light blocking pattern extend toward the same side of the display substrate.

8. The display substrate of claim 2, further comprising an organic insulating layer on the insulating layer to cover the second conductive line and the switching element, the organic insulating layer having a contact hole that extends to the drain electrode.

9. The display substrate of claim 1, wherein the switching element further comprises:
a gate electrode electrically connected to the first conductive line; and
a source electrode electrically connected to the second conductive line.

10. The display substrate of claim 9, further comprising a gate insulating layer on the insulating substrate to cover the first conductive line, the storage capacitor line, the light blocking pattern and the gate electrode.

11. The display substrate of claim 10, further comprising:
a passivation layer on the gate insulating layer to cover the second conductive line, the source electrode and the drain electrode; and
an organic insulating layer on the passivation layer,
wherein the pixel electrode is electrically connected to the drain electrode through a contact hole that is formed through the passivation layer and the organic insulating layer.

12. The display substrate of claim 1, wherein a common voltage is applied to the storage capacitor.

13. A display substrate comprising:
a first conductive line on an insulating substrate;
a storage capacitor line on the insulating substrate, the storage capacitor line extending substantially parallel to the first conductive line;
a second conductive line on the insulating substrate, the second conductive line extending in a direction different from the first conductive line, the first and second conductive lines defining a pixel;
a third conductive line spaced apart from the storage capacitor line on the insulating substrate, the third conductive line extending substantially parallel to the first conductive line;
a light blocking pattern extending from the third conductive line and overlapping with the second conductive line;
a switching element electrically connected to the first and second conductive lines, the switching element including a drain electrode positioned on the storage capacitor line to form a storage capacitor; and
a pixel electrode in the pixel electrically connected to the drain electrode.

14. The display substrate of claim 13, wherein a level of a direct current voltage applied to the third conductive line is substantially the same as an average level of a signal applied to the second conductive line.

15. The display substrate of claim 13, further comprising an auxiliary light blocking pattern extending from the storage capacitor line and overlapping with the second conductive line.

16. A method of manufacturing a display substrate, comprising:
forming a conductive line on an insulating substrate;
patterning the conductive line to form a gate line, a gate electrode electrically connected to the gate line, a storage capacitor line extending substantially parallel to the gate line and a light blocking pattern extending from the gate line;
forming a data line overlapping the light blocking pattern, a source electrode electrically connected to the data line, and a drain electrode spaced apart from the source electrode, the drain electrode positioned on the storage capacitor line; and
forming a pixel electrode in a pixel defined by the gate and data lines, the pixel electrode being electrically connected to the drain electrode.

17. The method of claim 16, wherein forming the gate line, the gate electrode, the storage capacitor line and the light blocking pattern further comprises patterning the conductive pattern to form an auxiliary light blocking pattern extending from the storage capacitor line and overlapping the data line.

18. A method of manufacturing a display substrate, comprising:
forming a conductive line on an insulating substrate;
patterning the conductive line to form a gate line, a gate electrode electrically connected to the gate line, a storage capacitor line extending substantially parallel to the gate line, a compensation voltage supplying line extending substantially parallel to the gate line to be spaced apart from the storage capacitor line, and a light blocking pattern extending from the compensation voltage supplying line;
forming a data line overlapping the light blocking pattern, a source electrode electrically connected to the data line and a drain electrode spaced apart from the source electrode, the drain electrode positioned on the storage capacitor line; and
forming a pixel electrode in a pixel defined by the gate and data lines, the pixel electrode being electrically connected to the drain electrode.

19. The method of claim 18, wherein forming the pixel electrode further comprises partially overlapping the compensation voltage supplying line with the pixel electrode to form an auxiliary storage capacitor.

20. A display device comprising:
a display substrate including:
a first conductive line on an insulating substrate;
a storage capacitor line on the insulating substrate, the storage capacitor line extending substantially parallel to the first conductive line;
a second conductive line on the insulating substrate, the second conductive line extending in a direction different from the first conductive line, the first and the second conductive lines defining a pixel;
a third conductive line spaced apart from the storage capacitor line on the insulating substrate, the third conductive line extending substantially parallel to the first conductive line;
a light blocking pattern extending from the third conductive line and overlapping the second conductive line;
a switching element electrically connected to the first and second conductive lines, the switching element including a drain electrode positioned on the storage capacitor line to form a storage capacitor; and
a pixel electrode in the pixel electrically connected to the drain electrode;
a cover substrate including a common electrode facing the pixel electrode; and
a liquid crystal layer interposed between the display substrate and the cover substrate.

21. The display device of claim 20, wherein a direct current voltage is applied to the third conductive line.
